(19) United States
(12) Patent Application Publication
(10) Pub. No.: US 2005/0257822 A1
(43) Pub. Date: Nov. 24, 2005

(54) Silk-screen thermocouple

(75) Inventors: Toby E. Smith, Broken Arrow, OK (US); Craig L. Cooper, Inola, OK (US)

Correspondence Address: FELLERS SNIDER BLANKENSHIP;BAILEY & TIPPENS, THE KENNEDY BUILDING, 321 SOUTH BOSTON SUITE 800, TULSA, OK, 74103-3318, US

(73) Assignee: BED-CHECK CORPORATION

(21) Appl. No.: 11/132,772

(22) Filed: May 19, 2005

Related U.S. Application Data
(60) Provisional application No. 60/572,535, filed on May 19, 2004.

(51) Int. Cl. H01L 35/30

(52) U.S. Cl. 136/205; 136/212; 136/211

(57) ABSTRACT

There is provided herein a thermocouple and method of manufacturing same, which is preferably created by imprinting one or more non-conductive surfaces such as polyethylene with inks made of two different finely powered metals, the two constituent metals being chosen such that when they are placed in contact with each other thermocouple effect is created. According to a preferred embodiment, a finely powered metal ink containing, for example, iron would first be silk screened onto a substrate. Then a second metal ink would be screened onto the same substrate so as to intersect the first, the second metal being preferably being some combination of nickel and copper. By attaching electrodes to this screened combination, it will be possible to monitor temperature changes by measuring the current generated thereby.

### RELATED APPLICATION

This application claims the benefit of U.S. Provisional Patent Application Ser. No. 60/572,535 that was previously filed on May 19, 2004.

### FIELD OF THE INVENTION

The present invention relates generally to thermocouples for use in sensing temperature and for use in heating and cooling. More particularly, the instant invention involves the design, manufacture, and operation of printed thermocouples.

### BACKGROUND OF THE INVENTION

Thermocouples are widely used in science and industry for both temperature measurement and temperature control. Broadly speaking, the thermocouple effect is based on the observation that in certain circumstances a temperature differential can be converted directly into electrical energy, with the amount of electrical energy so generated providing an estimate of the temperature. Conventional thermocouples are often formed by joining together a pair of dissimilar metal wires, the metals having been chosen so that a voltage is observed depending on the size of the temperature difference between the joined and free ends of the pair. The observed voltage (which might be several μV per degree Celsius of observed temperature difference) then provides an estimate of the temperature differential along the length of the pair of wires according to standard equations well known to those of ordinary skill in the art.

Conversely, if a voltage is applied to a thermocouple a temperature differential is created between the junction and the free ends of the two elements that comprise the thermocouple, with the junction being either cooled or heated depending on the direction of the applied DC current. If a number of such thermocouples are interconnected, a heating and cooling module (e.g., a Peltier module) may be constructed according to methods well known in the art. Several thermocouples that have been interconnected in series are often also commonly referred to as a thermopile.

As useful and versatile as modern thermocouples might be, they suffer from certain disadvantages, among which are that they are generally not suitable for use on flexible/irregularly surfaces. Thermocouples are often made of thin wire pairs so that the device responds more quickly to temperature changes, but such a construction can make the thermocouple somewhat fragile.

Heretofore, as is well known in the thermocouple arts, there has been a need for an invention to address and solve the above-described problems. Accordingly, it should now be recognized, as was recognized by the present inventor, that there exists, and has existed for some time, a very real need for a thermocouple that would address and solve the above-described problems.

Before proceeding to a description of the present invention, however, it should be noted and remembered that the description of the invention which follows, together with the accompanying drawings, should not be construed as limiting the invention to the examples (or preferred embodiments) shown and described. This is so because those skilled in the art to which the invention pertains will be able to devise other forms of this invention within the ambit of the appended claims.

### SUMMARY OF THE INVENTION

In accordance with a preferred embodiment of the instant invention, a thermocouple, and a method of manufacturing the same, is taught herein that is designed to produce an element that is more reliable and can be manufactured with less cost than has heretofore been possible.

According to the instant invention, there is provided a thermocouple, and method of manufacturing the same, which is created by silkscreen printing two finely powered metals (or other thermocouple-active materials) onto a non-conductive substrate such as polyester. That is, and according to a first preferred embodiment, a finely powered metal such as iron would first be silk screened onto a non-conductive surface. This will preferably be followed by silk-screening a second metal, which might be some combination of nickel and copper, onto the same surface so as to intersect the region that has been imprinted in the first metal. Note that in some preferred embodiments, the thermocouple will be printed on two different surfaces that are brought into contact during assembly or subsequently during use. Then, by attaching electrical connectors to each element of this screened combination, it will be possible to monitor temperature changes by measuring the voltage generated by this printed combination.

According to another aspect of the instant invention, there is provided a method of manufacturing thermocouples which involves screening finely powered metals onto a nonconductive (or semi-conductive) surface. According to a first aspect of this invention, two dissimilar metals will be obtained in powered form. Such powered metals will preferably then be separately combined with a binding agent to produce two different inks that have thermocouple properties.

As a preferred next step, one of the two metalized inks will be selected and silk screened (e.g., screen printed, etc.) onto the non-conductive surface (or surfaces) according to a predetermined pattern. Then, preferably in a second pass, the second of the two metalized inks will be added, thereby forming one or more thermocouples. Following this, at least one pair of electrical contacts will be added to enable the amount of current generated by the thermocouples to be measured and, hence, the temperature estimated according to methods well known to those of ordinary skill in the art.

After the thermocouple pattern has been printed, it is preferred that a second non-conductive layer which is commensurate in size with the first be bonded thereto (e.g., by heat sealing, adhesive, etc.), thereby rendering the sensor resistant (or, preferably, impervious) to fluids. In one preferred arrangement the outer members will be comprised of a material such as polyester, preferably separated by one or more layers of polyethylene, the resulting “sandwich” being readily adapted to be heat sealed. In another preferred arrangement, one of the metalized inks will be printed on each of the non-conductive layers, with the inks coming into contact either when the two layers are assembled/bonded together or afterward during use if the intent is that the sensor functions as both a thermocouple and as a patient presence/absence monitor.

Additionally, it should be noted and remembered that although the instant thermocouple will preferably be created by silk-screening, other printing technologies could also be used including, without limitation, ink jet, offset printing, or any other printing method that is suitable for use with an ink that contains a powered metal therein.

Finally, those of ordinary skill in the art will recognize that although the ink that is used to create the inventive thermocouple has often been referred to herein as a “metallic” ink, in reality the materials that are used in the inks need not necessarily be comprised of a powered metal. Instead, a variety of non-metallic substances such as carbon, germanium, selenium, silicon, etc., could certainly be powered and used in some circumstances. In brief, any material (or combination of materials) with an appropriate Seebeck coefficient could conceivably be produced in powered form and used as a component of the instant invention.

The foregoing has outlined in broad terms the more important features of the invention disclosed herein so that the detailed description that follows may be more clearly understood, and so that the contribution of the instant inventors to the art may be better appreciated. The instant invention is not to be limited in its application to the details of the construction and to the arrangements of the components set forth in the following description or illustrated in the drawings. Rather, the invention is capable of other embodiments and of being practiced and carried out in various other ways not specifically enumerated herein. Further, the disclosure that follows is intended to be pertinent to all alternatives, modifications and equivalents as may be included within the spirit and scope of the invention as defined by the appended claims. Finally, it should be understood that the phraseology and terminology employed herein are for the purpose of description and should not be regarded as limiting, unless the specification specifically so limits the invention.

While the instant invention will be described in connection with a preferred embodiment, it will be understood that it is not intended to limit the invention to that embodiment. On the contrary, it is intended to cover all alternatives, modifications and equivalents as may be included within the spirit and scope of the invention as defined by the appended claims.

### BRIEF DESCRIPTION OF THE DRAWINGS

Other objects and advantages of the invention will become apparent upon reading the following detailed description and upon reference to the drawings in which:

FIG. 1 illustrates a preferred thermocouple arrangement.

FIG. 2 contains a preferred cross sectional view of the point of intersection of the embodiment of FIG. 1.

FIG. 3 illustrates a preferred configuration of a Peltier module which is comprised of thermocouples constructed according to the instant invention.

FIG. 4 contains a preferred thermocouple arrangement for use as patient exit monitor.

FIG. 5 illustrates the embodiment of FIG. 3 which has been modified to allow for more efficient heat transfer.

FIG. 6 contains a top view of a preferred thermocouple array and electronic monitor for use therewith.

FIG. 7 contains an illustration of a cross sectional view of the embodiment of FIG. 6.

FIG. 8 illustrates another preferred embodiment wherein a single thermocouple manufactured according to the preferred method has multiple contact points.

FIG. 9 contains a preferred Peltier module configuration using materials deposited thereon by printing according to the methods taught herein.

FIG. 10 illustrates the embodiment of FIG. 9 prior to assembly.

FIG. 11 contains another preferred embodiment which can function both as a thermocouple circuit and as a presence/absence circuit.

FIG. 12 illustrates the embodiment of FIG. 12 before and during compression by the weight of a patient.

FIG. 13 illustrates another preferred thermocouple arrangement wherein the thermocouple will only be activated when a patient is present.

FIG. 14 illustrates the general environment of one aspect of the instant invention.

### DETAILED DESCRIPTION OF THE INVENTION

Turning first to FIG. 1 wherein is illustrated a first preferred embodiment, there is provided a method and apparatus for creating a thermocouple by silk screening or a similar printing process.

According to a first preferred embodiment and as is generally indicated in FIG. 1, a thermocouple 100 will preferably be silk screened or otherwise printed onto a nonconductive surface 145 using inks that have been specially prepared for that purpose. In more particular, and as is described more fully hereinafter, at least two different inks will be used to form the thermocouple 100, each ink containing a substantial amount of a different powered metal therein. The different inks will be used to print a pattern on the nonconductive surface that operates as a thermocouple, i.e., the two conductive arms 110 and 120 preferably intersect at a single point 115 as indicated. Thus, a temperature differential between the intersection point 115 and the reference junction (e.g., the temperature sensor interface circuit 130) will produce a voltage in the circuit 100, the magnitude of which is related to the temperature difference between the reference junction and the point of intersection 115. Of course, in the alternative, and as is discussed more fully below, if a current is applied to arms 110 and 120 that will result in a heating or cooling at the intersection point 115 depending on the polarity of the current.

In one preferred arrangement, the surface 145 on which the thermocouple 100 is printed will be comprised of one or more plastic-like materials such as polyester. Polyester, and especially polyester in sheet or film form, is preferred in applications wherein the temperatures that are to be measured are relatively low (e.g., from about 80 to 120 degrees Fahrenheit). This material is relatively inexpensive, flexible, and resistant to moisture which are properties that are especially desired in fields such as patient monitoring. That being said, those of ordinary skill in the art will recognize that in some instances it might be advantageous to utilize a substrate that has some limited amount of conductivity (e.g., a semi-conductive material). Thus, although the preferred embodiment utilizes a substrate that is nonconductive it should be noted and remembered that other possibilities are certainly possible and have been contemplated by the inventors.

According to a first preferred embodiment, and as is generally set out in FIG. 1, there is provided a thermocouple 100 that has been imprinted on one or more non-conductive surfaces 145. In one preferred embodiment, a first thermocouple arm 110 will be printed with ink that contains powered metal therein. For example, the metal might be copper, cadmium, aluminum, platinum, rhodium, nickel-chromium, nickel-aluminum, lead, silver, gold, etc. and also combinations or alloys of the same. Those of ordinary skill in the art will recognize that many different metals might be employed, but certain metals are preferred for their predictable output voltages when used as a component of a thermocouple.

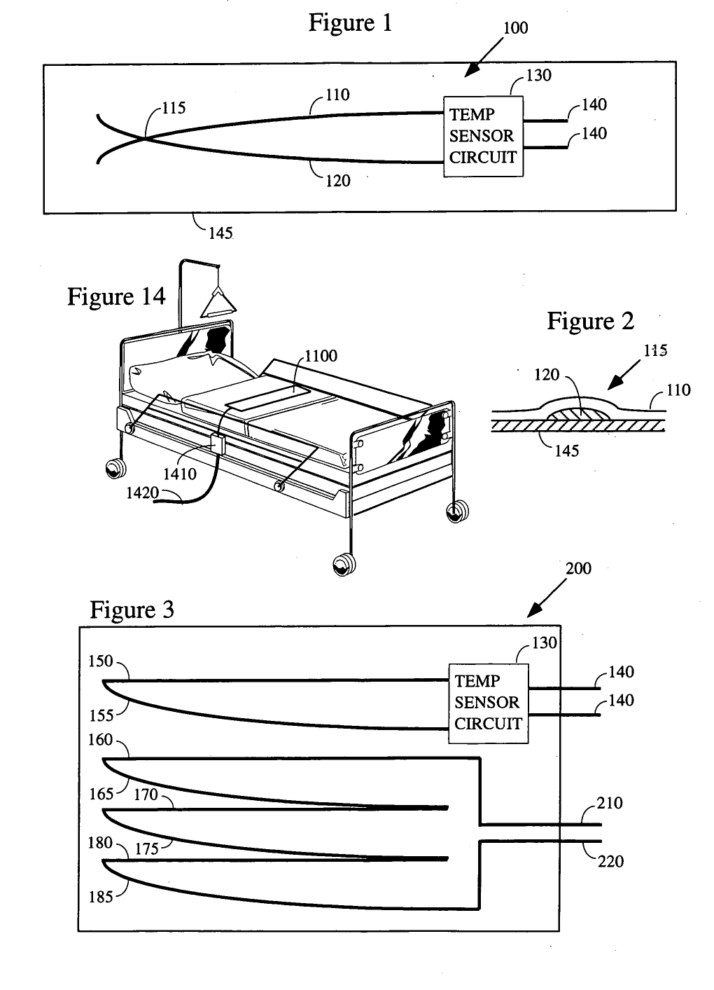

The second thermocouple arm 120 will then be printed (either on the same or on the opposite non-conductive substrate) so as to intersect arm 115 the first thermocouple element 110, and, further, will contain powered metal of a sort that is calculated to create a thermocouple effect when joined where it intersects 115 with the first arm 110. As is best illustrated in the cross sectional view of the intersection point of the two arms (FIG. 2), it is preferred that the first arm 110 be in direct contact with the second arm 120 by, for example, printing it directly atop the other element.

Preferably, the thermocouple pair 110/120 will then be placed in electrical communication with a temperature sensor interface circuit 130, which is designed to measure the voltage generated by the thermocouple and correct that voltage by an amount that is related to the temperature at the sensor 130 which preferably is the reference junction for the thermocouple circuit 100. Those of ordinary skill in the art will recognize that many circuits of the same general sort as temperature circuit 130 are readily available and would be suitable for use with the instant invention.

Turning next to another preferred embodiment and as is generally indicated in FIG. 3, there is provided a thermocouple substantially as described previously, but wherein multiple thermocouples are arranged to form a module for heating and/or cooling (e.g., a Peltier module) and wherein multiple thermocouples are printed onto a non-conductive surface by silk screening or similar printing means. As has been described previously, it is preferred that each of the thermocouples in module 200 be placed on a non-conductive surface such as polyester or other plastic. Additionally, and as has been discussed previously, each of the arms of the thermocouple pairs is made of an ink containing a different powdered metal than that of the arm that intersects it. For example, arms 150 and 155 contain different powered metals, arms 160 and 165 are printed with different powered metals, etc. Although this type of module might be implemented in many different ways, it is preferred that one of the thermocouple pairs (e.g., thermocouple 150/155) be used as a temperature sensor so that the temperature of the module 200 may be determined for control purposes via electrical contacts 140, which explains the inclusion of temperature sensor interface circuit 130. It should be clear to those of ordinary skill in the art that the utilization of such a temperature sensor circuit 130 is not required and, as such, is only a preferred aspect of this particular embodiment.

Additionally, it should be clear by reference to FIG. 3 that in the preferred arrangement electrical contacts 210/220 will be used to deliver an electrical current to the thermocouple pairs 160-185, for purposes of heating or cooling depending on the polarity of the charge applied thereto.

FIG. 5 illustrates another preferred variant of the invention of FIG. 3. In the embodiment of FIG. 5, heat conductors 590 have been added at the point of intersection between the two dissimilar metallic inks. This enhancement would assist in the collection and distribution of heat, depending on whether the module 500 was used as a heating or cooling unit. In one preferred embodiment, the heat conductors 590 will be copper (or other heat conducting) disks that are placed into thermal communication with the intersection point of the thermocouple and preferably will be separated electrically from the junction by the application of a nonconductor to the underside of the collector 590 or atop the intersection.

FIG. 8 illustrates still another preferred embodiment, wherein a thermocouple has been created with a plurality of intersection points 830 that are configured in parallel, so that if one of these points 830 were to fail for some reason and result in a loss in electrical conductivity across that one point, the others would continue to operate. As is generally indicated in that figure, two dissimilar metal inks are used to print the arms 810 and 820 of the instant thermocouple. In this configuration, if one of the intersection points 830 between the two dissimilar metals becomes broken, the remaining points 830 will still function normally. Note that this figures illustrates one clear advantage of the instant invention, i.e., it allows uniquely shaped and configured thermocouples to be formed that could not be easily or economically formed using methods available in the prior art. Any shape that can be printed—whether functional or decorative—could potentially be used in forming a thermocouple according to the methods taught herein.

Finally, it should be clear to those of ordinary skill in the art that thermocouples formed according to the instant invention are suitable for any use in any application that a conventional thermocouple would be used, except that the instant invention will likely not be suitable for use at the highest temperatures. However, for applications wherein the expected temperatures may be found in a relatively modest temperature range (e.g., temperatures that are suitable for use with human subjects, say, within 75° F. or so of room temperature), the instant invention would be ideal.

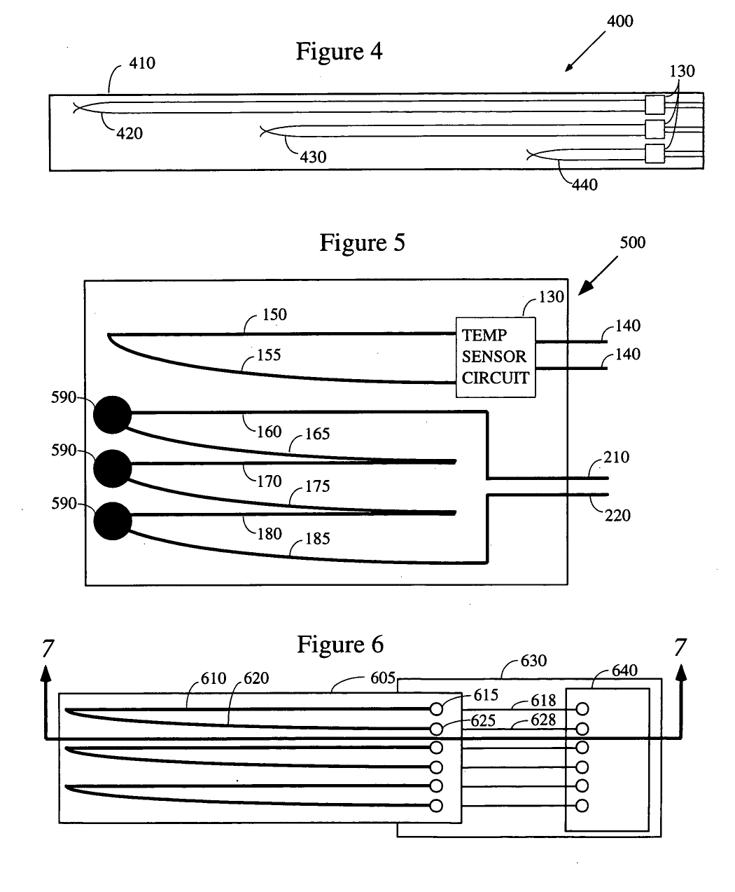

As an example of one application that would be well suited for use with a thermocouple of the sort taught herein, one or more of the embodiments 100 of FIG. 1 could readily be made into a sensor 400 (FIG. 4) for determining the presence or absence of a patient within a bed or chair. In one preferred arrangement, a plurality of thermocouples 420, 430, and 440 that have been formed according to the instant invention will be imprinted on a surface 410 that is made of a flexible, waterproof, and nonconductive material such as polyester (or, for example, layers of polyester). Preferably, the surface 410 upon which the thermocouples are printed will be sealed to another comparably sized surface of the same material, thereby enclosing the thermocouples 420-440 therein and protecting them from exposure to moisture, dust, and other contaminants. Then, when the instant sensor 400 is placed underneath a seated or lying patient, the thermocouples 420-440 will respond to the patient's body heat and a microprocessor or other signal conditioning device that is placed into electrical communication with temperature sensor circuits 140 will be able to determine a temperature from the thermocouple and, by virtue of that measurement, obtain an indication as to whether or not the patient is still present.

As still another example of an application that could benefit from the user of the instant thermocouple 100, those of ordinary skill in the art will recognize that the instant invention would be especially suitable for use in detecting the early stages of pressure ulcer formation in an immobile patient. As is well known in the medial arts, pressure ulcers typically form at pressure points where the patient's body weight rests on bony prominences. People who are bedfast or long-term residents therein tend to develop pressure ulcers over the hip, spine, lower back, shoulder blades, elbows, and heels. Similarly, people who are confined to a wheelchair tend to develop pressure ulcers on the lower back, buttocks and legs. In either case, the pressure of the patient's weight temporarily cuts off the skin's blood supply to a portion of the weight bearing soft tissue. This injures the patient's skin cells and can cause those cells to die in a fairly short period of time unless the pressure is relieved and blood is allowed to flow to the ischemic tissue again. A generally recognized precursor to pressure ulcer formation is that the affected region of the soft tissue can change in temperature as compared with the rest of the patient's body. Thus, it may be possible to recognize and avert ulcer formation by continuously monitoring the patient's body temperature in regions of the body that could be subject to the development of pressure ulcers. The embodiment of FIG. 4 would be useful for this application.

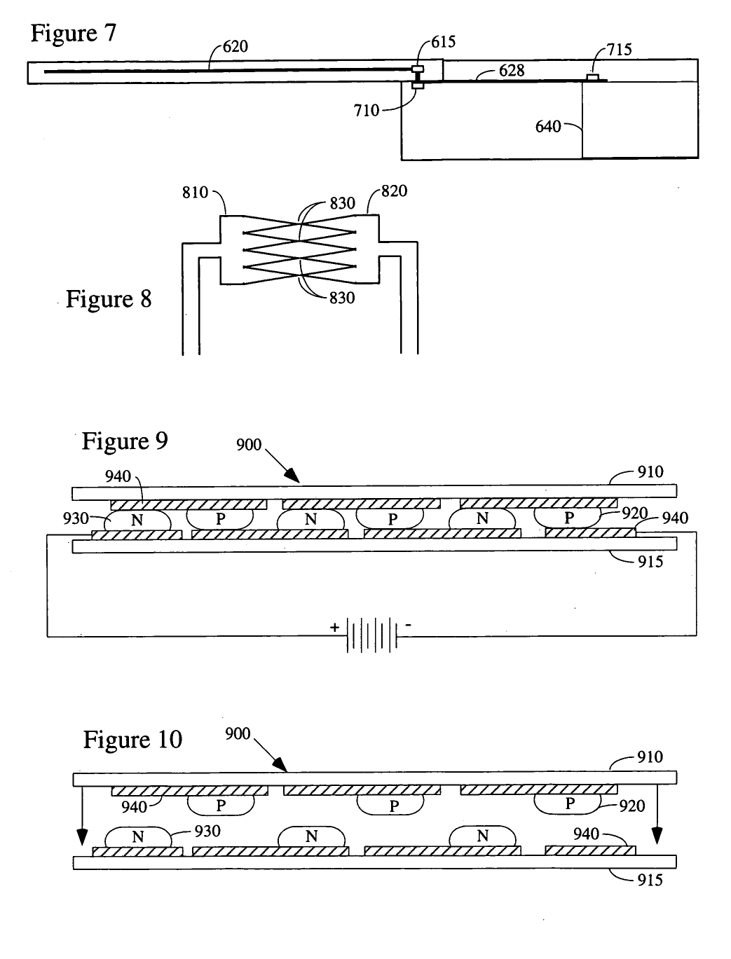

FIGS. 6 and 7 illustrate how an electronic patient monitor 630 might be used to form a personal environmental control apparatus that utilizes a preferred embodiment of the instant invention. Not shown in FIGS. 6 and 7 are a power supply, a microprocessor or similar signal conditioning device, and (optionally) at least one temperature sensor. As is best seen in FIG. 6, the thermocouples of FIG. 5 would preferably be incorporated into a mat 605 or similar thin, planar, waterproof, flexible assembly that can be placed beneath a patient. Preferably there will be a plurality of thermocouple pairs 610/620, each of which is comprised of dissimilar metal inks as has been discussed previously. In the preferred arrangement the thermocouple pairs 610/620 will terminate within the mat 605 in connectors 615 and 625, each of which will preferably be of the same type of metal as that which is included in the metallic ink that was used to print the thermocouples. Each of the connectors 625/615 will preferably engage connectors within the monitor 630 of the same metal type. Finally, and as is illustrated most clearly in FIG. 7, the internal connector 710 will be preferably interconnected via a same-metal metallic wire 628/618 to a heat sink 725. The connector 715 could either be of the same or a different metal than the wire 628.

One purpose of this arrangement is to move the reference junction for temperature measurement inside of the monitor 630 and into contact with a heat sink 640, which might utilize fins, fans, etc., to dissipate (output) thermal energy that is provided thereto by the thermocouples. Of course, in the event that the thermocouples are cooling the heat sink 640 (e.g., if the goal is to apply heat to the patient via the thermocouples) the same fins, fans, etc., will serve to input thermal energy (i.e., to warm it). Those of ordinary skill in the art will recognize that this arrangement will make it possible to apply spot heating and cooling to a patient or, for that matter, to anyone who requires same (e.g., a spectator at an outdoors sporting event game, a hunter, skier, a driver or passenger who is seated in an automobile seat, etc.).

In one preferred arrangement, a temperature differential of about 5° F. might be generated between the reference temperature and the intersection point of the thermocouple by application of, for example, about 300 milliamps of drive current. Those of ordinary skill in the art will recognize that there are many variations of the previous embodiment that could be constructed so as to yield alternative temperature differentials and/or require different amounts of drive current. Obviously, such properties are related to a choice of a particular set or combination of materials in the thermocouple ink, the selection of such being a design choice that is well within the capability of one of ordinary skill in the art.

According to another preferred embodiment and as is generally indicated in FIG. 9, there is provided a thermocouple 900 arrangement configured in the form of a Peltier module. As is indicated in this figure (which is a cross sectional view of the instant device), the “P” type 920 (i.e., “positive”) and “N” type 930 (i.e., “negative”) thermocouple elements are preferably printed in alternating parallel rows of pads atop discontinuous conductive elements 940 which are designed to form a conductive bridge between adjacent thermocouple elements 920 and 930. Substrates 910 and 915 are preferably non-conductive as has been discussed previously. In operation, after the power source has been activated it delivers a predetermined current to the conductive elements 940 which interconnect the “P” 920 and “N” 930 thermocouple elements, thereby either heating or cooling the module 900 depending on the direction of the current flow.

FIG. 10 illustrates more clearly how the embodiment of FIG. 9 might appear prior to assembly, i.e., after preparing upper and lower substrates 910 and 915 and bringing them into alignment. The “N” type 930 and “P” type 920 thermocouple elements will preferably have been previously printed into separate substrate members 910 and 915 before the two substrates 910 and 915 are brought together for purposes of joining them together and sealing them at least around their peripheries. As is well known to those of ordinary skill in the art, the two members 910/915 could be joined together in many ways including heat sealing, adhesives, etc.

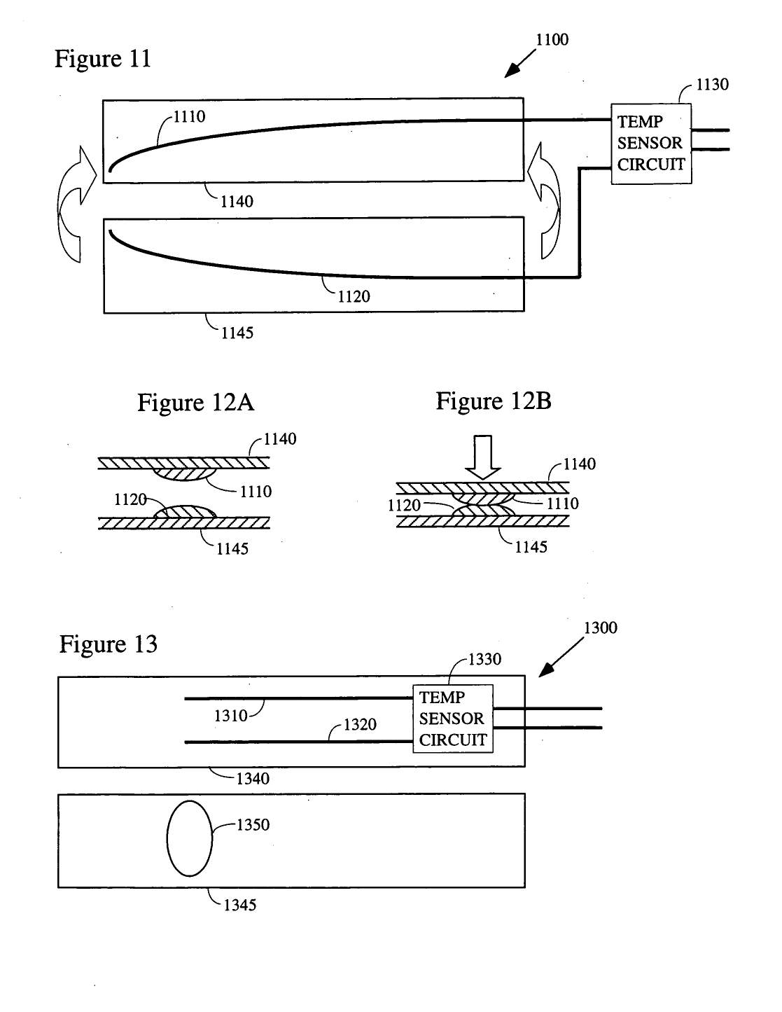

In still another preferred embodiment, that the instant inventors have devised a thermocouple substantially similar to that discussed previously, but which also functions as a sensor for monitoring, for example, the presence or absence of a patient in a bed. As is generally indicated in FIG. 11, in this preferred variation the sensor 1100 will preferably be formed using two separate substrate members 1140 and 1145, with one arm 1110/1120 of the thermocouple printed on each. Assembly of the sensor 1100 will preferably include insertion of a resilient/elastic spacing member between the two substrate members 1140 and 1145. As is conventionally done, the spacing member will have one or more apertures therethrough to allow the thermocouple arms 1110/1120 to remain separated so long as the sensor 1100 is not under compression but be forced into contact through such aperture(s) when compression is applied. Although the spacer is not pictured in FIG. 11, the use of this sort of element is well known to those of ordinary skill in the pressure sensitive switch arts as is illustrated, for example, in U.S. Pat. No. 6,417,777, the disclosure of which is incorporated herein by reference. After the sensor 1100 is assembled (e.g., by flipping the substrate 1145, placing it atop substrate 1140, inserting the spacer, and sealing the edges according to methods well known to those of ordinary skill in the pressure sensitive switch arts) it will preferably be placed underneath a patient. In the preferred arrangement the two arms 1110/1120 will not be in electrical contact until after pressure (e.g., a patient's weight) is placed on the sensor (e.g., FIG. 12A). However, if weight is applied (FIG. 12B), the sensor 1100 will collapse, causing the thermocouple arms 1110/1120 to come into contact and thereby completing the thermocouple circuit so that an attached signal processing device can read and interpret signals from the temperature sensor circuit 1130.

In operation and as is generally indicated in FIG. 14, the sensor 1100 (which would conventionally take the form of a mat) will be placed in a bed or chair. A separate electronic patient monitor 1410 will monitor the status of the sensor 1100 and, in one preferred arrangement, communicate that status to a remote caregiver via, for example, a connection 1420 to a nurse call or similar interface. Wireless connectivity to a remote caregiver is, of course, a well-known alternative to the wired connection 1420 that is illustrated in FIG. 14. Preferably the monitor 1410 will include a microprocessor or similar programmable circuitry (e.g., a gate array, PLD, etc.) to allow it to process and respond to signals from the sensor 1100. When a patient is present on the sensor 1100, the patient's weight will compress it and complete the thermocouple circuit. The attached monitor 1410 will then receive temperature data from the sensor 1100 and/or be able to initiate heating/cooling of the patient via one ore more thermocouple elements within the sensor 1100 as has been discussed previously. However, if the patient should leave the bed, the thermocouple circuit will be broken and the monitor 1410 will not be able to detect temperature readings. In such an instance, depending on the programming of the monitor, a caregiver might be notified of that fact via an audio alarm built into the monitor 1410 and/or a signal might be sent to a remote caregiver.

As still another preferred variation of the previous pressure activated thermocouple, there is provided the arrangement of FIG. 13 wherein both thermocouple arms 1310/1320 are printed on the same substrate 1340. In this embodiment, a conductive pad 1350 is placed opposite the thermocouple arms 1310/1320 and brings the two into electrical contact when pressure is applied to the sensor 1300. As before, the pad 1350 will preferably be kept away from the thermocouple arms 1310/1320 by a resilient central spacer (not shown), the stiffness of the substrate material(s) 1340/1345, or some similar mechanism. As before, when pressure is brought to bear on the sensor 1300 an attached monitoring device will be able to read the temperature sensor circuit 1330 and interpret the signals (or lack of same) obtained therefrom.

Turning next to a preferred method of manufacturing the instant invention, there is provided a method for printing thermocouple elements on one or more nonconductive surfaces that utilize silk screening or a similar printing mechanism. In the preferred embodiment and as a first step, powered metal of two different kinds will be obtained. These products are readily available commercially and can be ordered in particle sizes from very fine to coarse (e.g., from about 0.1 to 1000 microns) for a variety of different metals. The choice of a particle size will be dependent to some extent on the particular application and the methodology by which particles are applied to the insulating substrate. Those of ordinary skill in the art will recognize that a certain amount of experimentation may be necessary in order to find a best particle size for a particular application.

As a next preferred step, each of the powdered conductive materials (i.e., powdered metals in this embodiment) will be combined with at least one binding agent and, additionally if needed, one or more solvents or other carriers to form a thermocouple ink. The choice of a binder will depend at least on part on the nature of the surface upon which the ink is to be deposited and the application method used; and should be chosen so that the powered conductive material will remain firmly affixed to the selected surface and in electrical communication with the other ink. Additionally, it would be advantageous if the binder were at least somewhat electrically conductive.

The function of the solvent, if it is used, is to increase the liquidity and mobility (e.g., decrease the surface tension, increase the wetability, etc.) of the resulting ink (i.e., decrease its viscosity) so that it can be applied easily. Volatile and/or nonvolatile solvents might be used depending on the particular application. Note that the composition of this component might need to be varied depending on the type of metal powder, the binder, and even the temperature and humidity at the time the thermocouples are to be printed, as is well known to those of ordinary skill in the printing arts.

The mixture of metal particles, binder, and solvents will then next be loaded into the printing device. As will be discussed at greater length below, preferably this will be a silk-screen printing apparatus. However, those of ordinary skill in the art will recognize that an ink jet printer, a color laser printer, offset printing, web-type printing, intaglio printing, screened/masked printing, vacuum deposition, and many other printing technologies could be used to print the thermocouple pattern. All that is required is that the ink dispensing mechanism be capable of printing multiple ink types (to include printing a single type of ink in two different passes) onto one or more selected surfaces.

However, in the instance that silk screen printing is employed, it is preferred that the screen be made of silk, stainless steel wire mesh cloth, mono filament mesh or a similar material. Clearly, the size of the mesh openings will be chosen, at least in part, as a function of the particle size in the ink. The pattern of the thermocouple(s) will be imprinted on this surface according to methods well known to those of ordinary skill in the art, e.g. by coating the screen with a photoactive emulsion, placing a “positive” of the thermocouple pattern in close proximity to the screen, and then exposing the combination to light, thereby creating a template through which the ink may be applied to the substrate. Preferably at least two indexed screens will be utilized, one for each type of metallic ink.

As a next preferred step, the substrate material(s) upon which the thermocouples are to be printed is placed in position for printing. As has been described previously, almost any nonconductive surface might be adapted for use as a substrate with the instant invention including, without limitation, plastics, rubber, cloth, ceramics, glass, etc. That being said, the instant invention will likely work best when placed on relatively inelastic materials.

Preferably, and as a next step, a first of the two screens will be selected and one of the metallic inks applied thereto according to methods well known to those of ordinary skill in the art. This will then preferably be followed by the application of the second ink (on the same or opposite side) by using the second screen. It should be clear that by using silkscreen methods, it would be straightforward to create the sort of material overlap as is illustrated in FIG. 2.

In one preferred embodiment the thermocouple legs will have a printed width of about 0.1 inches although it should be clear that many other widths could be appropriate depending on the particular application. It is expected that some degree of experimentation might be necessary in order to choose an appropriate width, since the width will likely vary depending, at least, on the thermocouple material in the ink, the binder or solvent, particle size, the substrate, etc.

### Conclusions

It should be noted that the various temperatures, materials, thicknesses, and other measurements associated with preferred embodiments disclosed herein are given for purposes of illustration only and should not construed to limit the practice of the subject matter claimed hereinafter. For example, although a polyester mat is a preferred substrate for the inventive thermocouples, that is only one of many thermally conductive materials that would be suitable for use with the instant invention. Of course, at minimum, the substrate must be electrically non-conductive. Additionally, it must be a surface that can accept a printed image. Beyond that, there are no specific material requirements and any number of non-conductive materials could be used (e.g., solid surfaces, cloth, rubber, polyester, plastics including polyethylene napthylate, polypropylenes, polycarbonates, high density polyethylene, polyurethane polystyrene, plastic impregnated textiles and webs, polyvinyl fluoride, plastic impregnated paper, ethyl-vinyl acetate, polyethylene, ethylene methyl acetate in mixture with ionimers, combinations of copolymers, ethylene acrylic acid, acetyl copolymers, laminates of any of the foregoing, etc.).

Additionally, it should be noted and remembered that although inks that are comprised of powered metals are the preferred embodiment, there are other non-metallic substances that could be used instead. For example, non-metallic conductive substances such as carbon, germanium, selenium, silicon, etc., could certainly be powdered and incorporated into an ink according to the methods taught herein. In brief, any combination of materials that have appropriate Seebeck coefficients (i.e., one thermocouple ink being comprised of a material with a positive coefficient and the other with a negative one) and that can be obtained in powered form could possibly be used to form a printed thermocouple according to the methods of the instant invention.

Further, although the instant thermocouple embodiments are primarily intended for heating and cooling, those of ordinary skill in the art will recognize that it is possible to use the instant invention to create, for example, a presence/absence detector that could be placed under a patient and that would make it possible for an attached electronic patient monitor to determine whether or not the patient is in contact with the detector (e.g., by monitoring for changes in temperature and/or continuity).

Additionally, those of ordinary skill in the art will recognize that a clear advantage of the instant method and apparatus is that it can create thermocouples on virtually any nonconductive substrate. Prior art methods that require sintering or melting are not suitable for use with substrates such as plastics that have relatively low melting points. Further, the instant method is suitable for use on flexible and porous materials such as fabric. Indeed, the instant inventors have determined that thermocouples that are printed on clothing could be used to heat or cool an individual, e.g., consider the case of a shirt that has a battery operated Peltier module imprinted thereon that could provide heating in the winter and cooling in the summer.

Those of ordinary skill in the art will recognize that there are many active devices that could serve for purposes of the instant invention as active portion of the patient monitor including, of course, a conventional microprocessor. More generally, the instant invention preferably includes an electronic monitor that utilizes some sort of active device, i.e., one that is programmable in some sense, is capable of recognizing signals from an attached patient sensing device, and is capable of initiating alarm sounds in response to a patient condition, such alarm sounds being transmitted to an internal, external, or remote speaker. Of course, these sorts of modest requirements may be satisfied by any number of programmable logic devices (“PLD”) including, without limitation, gate arrays, FPGA's (i.e., field programmable gate arrays), CPLD's (i.e., complex PLD's), EPLD's (i.e., erasable PLD's), SPLD's (i.e., simple PLD's), PAL's (programmable array logic), FPLA's (i.e., field programmable logic array), FPLS (i.e., fuse programmable logic sequencers), GAL (i.e., generic array logic), PLA (i.e., programmable logic array), FPAA (i.e., field programmable analog array), PsoC (i.e., programmable system-on-chip), SoC (i.e., system-on-chip), CsoC (i.e., configurable system-on-chip), ASIC (i.e., application specific integrated chip), etc., as those acronyms and their associated devices are known and used in the art. Further, those of ordinary skill in the art will recognize that many of these sorts of devices contain microprocessors integral thereto. Thus, for purposes of the instant disclosure the terms “processor,” “microprocessor” and “CPU” (i.e., central processing unit) should be interpreted to take the broadest possible meaning herein, and it should be noted that such meaning is intended to include any PLD or other programmable device of the general sort described above.

Note also that even though a microprocessor-based monitor is the preferred configuration, those of ordinary skill in the art will recognize that discrete components could also be used to duplicate the necessary functionality. Thus, for purposes of the instant invention an electronic patient monitor should be understood to include both microprocessor and non-microprocessor devices.

Thus, it is apparent that there has been provided, in accordance with the invention, a monitor and method of operation of the monitor that fully satisfies the objects, aims and advantages set forth above. While the invention has been described in conjunction with specific embodiments thereof, it is evident that many alternatives, modifications and variations will be apparent to those skilled in the art and in light of the foregoing description. Accordingly, it is intended to embrace all such alternatives, modifications and variations as fall within the spirit of the appended claims.

1. A thermocouple device, comprising:
(a) a substrate;
(b) a first thermocouple element printed on said substrate, said first thermocouple element being comprised of a first powered ink material; and,
(c) a second thermocouple element printed on said substrate, wherein at least a portion of said second thermocouple element is in electrical contact with said first thermocouple element, said second thermocouple element being comprised of a second powered ink material different from said first powered ink material, wherein said first and said second thermocouple elements taken together produce a thermocouple effect.

2. A thermocouple device according to claim 1, further comprising:
(d) a temperature sensor interface circuit in electrical communication with said first and said second thermocouple elements.

3. A thermocouple device according to claim 1, wherein said first and second thermocouple elements are printed on said substrate using silk-screen printing.

4. A thermocouple device according to claim 1, wherein said substrate is comprised of a material selected from a group consisting of plastic, cloth, rubber, polyester polyethylene napthylate, polypropylene, polycarbonate, high density polyethylene, polyurethane polystyrene, plastic impregnated textile, plastic impregnated web, polyvinyl fluoride, plastic impregnated paper, ethyl-vinyl acetate, polyethylene, ethylene methyl acetate in mixture with ionimers, ethylene acrylic acid, and acetyl copolymers.

5. A thermocouple device according to claim 1, wherein said first and second powered ink materials each contain at least one powered metal selected from a group consisting of copper, cadmium, aluminum, platinum, rhodium, nickel-chromium, nickel-aluminum, iron, tungsten, lead, silver, and gold.

6. A thermocouple device according to claim 1, wherein at least a portion of said first thermocouple element is in direct contact with said second thermocouple element, further comprising:
(d) a thermal collector in thermal communication with said point of direct contact between said first and second thermocouple elements.

7. A thermocouple device according to claim 6, wherein said thermal collector is a copper disk.

8. A thermocouple device according to claim 1, wherein
said first powered ink material comprises a first powered metal and a first binding agent, and,
said second powered ink material comprises a second powered metal different from said first powered metal and a second binding agent.

9. A thermocouple device according to claim 8, wherein said first and second binding agents are a same binding agent.

10. A thermocouple device according to claim 1, further comprising:
(d) a third thermocouple element printed on said substrate, said third thermocouple element being comprised of said first powered ink material; and,
(e) a fourth thermocouple element printed on said substrate, wherein at least a portion of said fourth thermocouple element is in electrical contact with said third thermocouple element, said fourth thermocouple element being comprised of said second powered ink material, wherein third and said fourth thermocouple elements taken together produce a thermocouple effect.

11. A Peltier module comprising a plurality of said thermocouple devices of claim 1 arrayed in close proximity with each other.

12. A thermocouple device according to claim 1, wherein said substrate is an inelastic substrate.

13. A thermocouple device according to claim 1, wherein said substrate is a non-conductive substrate.

14. A thermocouple device, comprising:
(a) a nonconductive substrate configurable to form a surface that is at least approximately planar;
(b) a first thermocouple element printed on said nonconductive substrate, said first thermocouple element being comprised of a first powered metal ink; and;
(c) a second thermocouple element printed on said nonconductive substrate, at least a portion of said second thermocouple element being in direct contact with said first thermocouple element, said second thermocouple element being comprised of a second powered metal ink different from said first powered metal ink, wherein first and said second thermocouple elements taken together produce a thermocouple effect;
(d) a first electrical connector in electrical communication with said first thermocouple element; and,
(e) a second electrical connector in electrical communication with said second thermocouple element.

15. A thermocouple device according to claim 14, wherein said first and second thermocouple elements are printed on said nonconductive substrate using silk-screen printing.

16. A thermocouple device according to claim 14, wherein said substrate is comprised of a material selected from a group consisting of plastic, cloth, rubber, polyester polyethylene napthylate, polypropylene, polycarbonate, high density polyethylene, polyurethane polystyrene, plastic impregnated textile, plastic impregnated web, polyvinyl fluoride, plastic impregnated paper, ethyl-vinyl acetate, polyethylene, ethylene methyl acetate in mixture with ionimers, ethylene acrylic acid, and acetyl copolymers.

17. A thermocouple device according to claim 14, wherein said first and second powered metal inks contain powered metal selected from a group consisting of copper, cadmium, aluminum, platinum, rhodium, nickel-chromium, nickel-aluminum, lead, silver, and gold.

18. A thermocouple device according to claim 14, further comprising:
(d) a thermal collector in thermal communication with said point of direct contact between said first and second thermocouple elements.

19. A thermocouple device according to claim 18, wherein said thermal collector is a copper disk.

20. A method of manufacturing a thermocouple device, comprising the steps of:
(a) obtaining a first powdered thermocouple material;
(b) obtaining a second powdered thermocouple material, wherein said first metal and said second thermocouple material taken together are suitable to produce a thermocouple effect;
(c) combining said first thermocouple material powder with at least a first binding agent, thereby forming a first thermocouple ink;
(d) combining said second thermocouple material powder with at least a second binding agent, thereby forming a second thermocouple ink;
(e) printing a first thermocouple element on a first surface using said first thermocouple ink; and,
(f) printing a second thermocouple element on a second surface using said second thermocouple ink, wherein said second thermocouple element is in electrical contact with said first thermocouple element at at least one location, thereby forming a thermocouple device.

21. A method of manufacturing a thermocouple device according to claim 20, wherein the steps (e) and (f) comprise the steps of:
(e1) silk-screen printing a first thermocouple element on a nonconductive surface using said first thermocouple ink; and,
(f1) silk-screen printing a second thermocouple element on said nonconductive surface using said second thermocouple ink, wherein said second thermocouple element is in direct contact with said first thermocouple element at at least one location.

22. A method of manufacturing a thermocouple device according to claim 20, wherein said first binding agent and said second binding agent are a same binding agent.

23. A method of manufacturing a thermocouple device according to claim 20, wherein said first thermocouple material is a first metal and said second thermocouple material is a second metal.

24. A method of manufacturing a thermocouple device according to claim 20, wherein said first surface and said second surface are a same surface.

25. A method of manufacturing a thermocouple device according to claim 20, wherein said first surface and said second surface are both non-conductive surfaces.

26. A thermocouple device, comprising:
(a) a first substrate;
(b) a first thermocouple element printed on said first substrate, said first thermocouple element being comprised of a first powered ink material;
(c) a second substrate positionable to be proximate to said first nonconductive substrate; and,
(d) a second thermocouple element printed on said second substrate, wherein said second thermocouple element is in electrical communication with said first thermocouple element, said second thermocouple element being comprised of a second powered ink material different from said first powered ink material, wherein said first and said second thermocouple elements taken together produce a thermocouple effect.

27. A thermocouple device according to claim 26, wherein said first and second thermocouple elements are brought into electrical contact only when said first and second substrates are compressed together.

28. A method of manufacturing a thermocouple device according to claim 26, wherein said first powdered ink material is a first powdered metal ink material and said second powdered ink material is a second powdered ink material.

29. A method of manufacturing a thermocouple device according to claim 26, wherein said first and second substrates are both comprised of a semi-conductive material.
